(19) United States
(12) Patent Application Publication
(10) Pub. No.: US 2012/0119245 A1
(43) Pub. Date: May 17, 2012

(54) LIGHT-EMITTING DEVICE

(75) Inventor: Tzer-Perng CHEN, Hsinchu (TW)

(73) Assignee: Epistar Corporation, Hsinchu (TW)

(21) Appl. No.: 13/296,573

(22) Filed: Nov. 15, 2011

(30) Foreign Application Priority Data
Nov. 15, 2010 (TW) 099139304

(51) Int. Cl. H01L 33/50

(52) U.S. Cl. 257/98; 257/E33.06

(57) ABSTRACT

Disclosed is a light-emitting device comprising: a carrier comprising: a first side and a second side; a semiconductor light-emitting stack layer on the first side of the carrier, the semiconductor light-emitting stack layer comprising a first conductivity type semiconductor layer, an active layer, and a second conductivity type semiconductor layer ; and a first electrode structure electrically coupled to the second conductivity type semiconductor layer, the first electrode structure comprising: a main electrode surrounding the semiconductor light-emitting stack layer; an extending electrode extending from the main electrode onto the second conductivity type semiconductor layer; and an electrode pad coupling to the main electrode.

### TECHNICAL FIELD

The application relates to a semiconductor light-emitting device.

### DESCRIPTION OF BACKGROUND ART

Currently, the light-emitting diodes have a problem of current spreading. For most light-emitting diodes, an electrode pad is disposed on the light-emitting layer structure for current input. A common method to improve the current spreading is to form a current spreading layer on the light-emitting layer structure, and then the electrode pad is disposed on the current spreading layer. The material of the electrode pad is usually metal, which shades light from the light-emitting layer structure, and results in poor light extraction efficiency.

### SUMMARY OF THE DISCLOSURE

Disclosed is a light-emitting device comprising: a carrier comprising: a first side and a second side; a semiconductor light-emitting stack layer on the first side of the carrier, the semiconductor light-emitting stack layer comprising a first conductivity type semiconductor layer, an active layer, and a second conductivity type semiconductor layer ; and a first electrode structure electrically coupled to the second conductivity type semiconductor layer, the first electrode structure comprising: a main electrode surrounding the semiconductor light-emitting stack layer; an extending electrode extending from the main electrode onto the second conductivity type semiconductor layer; and an electrode pad coupling to the main electrode.

### BRIEF DESCRIPTION OF THE DRAWINGS

FIG. 1A illustrates a top view of a light-emitting device in accordance with the first embodiment of the present application.

FIG. 1B illustrates the cross sectional view of the structure along the A-A′ line in FIG. 1A.

FIG. 1C illustrates the cross sectional view of the structure along the B-B′ line in FIG. 1A.

FIG. 2A illustrates a top view of a light-emitting device in accordance with the second embodiment of the present application.

FIG. 2B illustrates the cross sectional view of the structure along the A-A′ line in FIG. 2A.

FIG. 3A illustrates a top view of a light-emitting device in accordance with the third embodiment of the present application.

FIG. 3B illustrates the cross sectional view of the structure along the A-A′ line in FIG. 3A.

FIG. 4A illustrates a top view of a light-emitting device in accordance with the fourth embodiment of the present application.

FIG. 4B illustrates the cross sectional view of the structure along the A-A′ line in FIG. 4A.

FIG. 4C illustrates a cross sectional view of a light-emitting device in accordance with the fifth embodiment of the present application.

FIG. 4D illustrates a cross sectional view of a light-emitting device in accordance with the sixth embodiment of the present application.

### DETAILED DESCRIPTION OF PREFERRED EMBODIMENTS

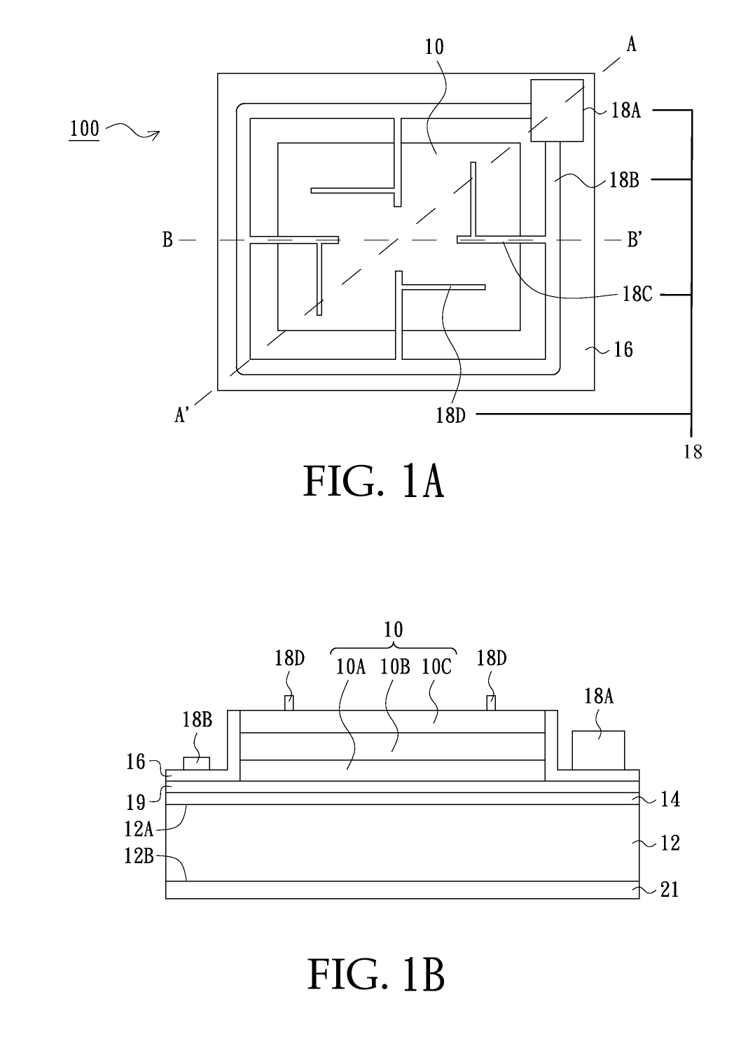

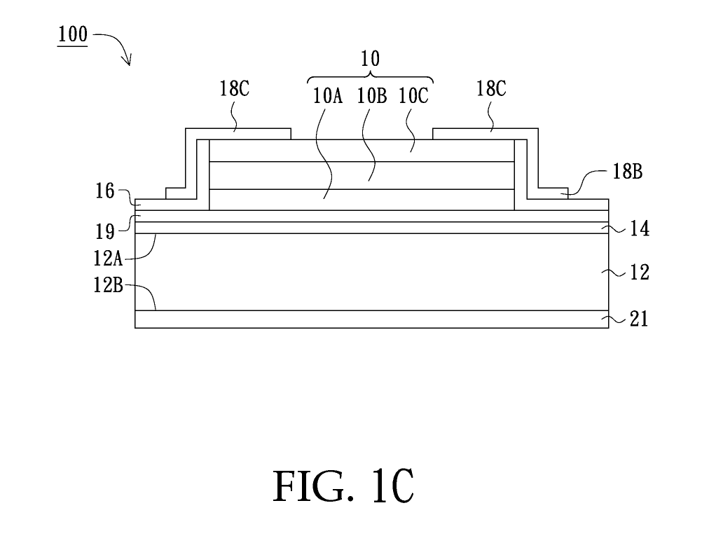

In FIG. 1A, a top view of a light-emitting device 100 in accordance with one embodiment of the present application is shown. The cross sectional view along the A-A′ line is shown in FIG. 1B, and the cross sectional view along the B-B′ line is shown in FIG. 1C. First, a semiconductor light-emitting stack layer 10 is formed on a growth substrate (not shown). The semiconductor light-emitting stack layer 10 comprises a second conductivity type semiconductor layer 10C, an active layer 10B, and a first conductivity type semiconductor layer 10A. The semiconductor light-emitting stack layer 10 may be a stack structure of layers formed by epitaxial growth with a material of GaN-based series, AlGaInP-based series, or other suitable semiconductor materials. In one embodiment, the area of the semiconductor light-emitting stack layer 10 is about between 0.25 mm² and 25 mm², and preferably between 1 mm² and 25 mm². The first conductivity type and the second conductivity type are different conductivity types. For example, when the first conductivity type semiconductor layer 10A is p-type, the second conductivity type semiconductor layer 10C is n-type; and vice versa. Then, a reflective layer 19 is formed on the first conductivity type semiconductor layer 10A. The reflective layer 19 is bonded to one side 12A of a carrier 12 with a bonding layer 14. Afterward, the growth substrate (not shown) is removed to expose the second conductivity type semiconductor layer 10C. The bonding layer 14 may be formed on the reflective layer 19 and then bonded to the carrier 12; or the bonding layer 14 may be formed on the carrier 12 and then bonded to the reflective layer 19; or a part of the bonding layer 14 may be respectively formed on the reflective layer 19 and the carrier and the two parts are bonded together. Carrier 12 is conductive, and the material comprises metal, such as one material selected from a group consisting of copper, aluminum, nickel, molybdenum, and tungsten, and the combination thereof, or semiconductor such as silicon or silicon carbide. The material of the bonding layer 14 comprises metal or metal alloy, such as one material selected from a group consisting of gold, silver, aluminum, indium, tin, and lead, and the metal alloy thereof. The material of the bonding layer 14 also comprises metal oxides such as indium tin oxide and other conductive materials. And then part of the semiconductor light-emitting stack layer 10 is etched to expose part of the reflective layer 19, and an insulating structure 16 is formed on the side walls of the semiconductor light-emitting stack layer 10 and the reflective layer 19. in one embodiment of the application, the insulating, structure 16 covers one side 12A of the carrier 12 and the side walls of the semiconductor light-emitting stack layer 10, but the second conductive type semiconductor layer 10C of the semiconductor light-emitting stack layer 10 is exposed. The material of the insulating structure 16 comprises silicon dioxide, silicon nitride, or aluminum oxide.

Then, a first electrode structure 18 is formed and electrically connected to the second conductivity type semiconductor layer 10C. The first electrode structure 18 mainly comprises an electrode pad 18A, a main electrode 18B, and an extending electrode 18C. As shown in FIG. 1A, the main electrode 18B surrounds the semiconductor light-emitting stack layer 10 and is connected to the electrode pad 18A, or specifically, the electrode pad 18A and/or the main electrode 18B are/is formed on an area of the carrier 12 not covered by the semiconductor light-emitting stack layer 10. In one embodiment of the application, the main electrode 18B is not in direct contact with and is separated with a gap from the semiconductor light-emitting stack layer 10 or the second conductivity type semiconductor layer 10C. As shown in FIG. 1A, the main electrode 18B is substantially located on an area not covered by the semiconductor light-emitting stack layer 10, and is on the insulating structure 16, and therefore it does not cover the second conductivity type semiconductor layer 10C. As the main electrode 18B is not located on the light extraction surface of the semiconductor light-emitting stack layer 10, the chance for the light shaded by the electrode is eliminated. Therefore, to conduct the current from the electrode pad 18A, the size of the main electrode 18B is designed to meet the requirement under the considerations of the current conduction and the current dispersion, rather than limited by the consideration of shading. The width of the main electrode 18B can be equal to or less than the width of the electrode pad 18A, so that the current conduction is improved, and the electrical characteristics of the light-emitting, device, such as series resistance or forward voltage, are not affected in one embodiment of the present application, the width of the main electrode 18B can be between 5 μm and 100 μm, and preferably between 21 μm and 100 μm for a high-power light-emitting device, and preferably between 51 μm and 100 μm for an even more high-power light-emitting device.

As shown in FIG. 1A, the extending electrodes 18C extend from the main electrode. 18B to the second conductivity type semiconductor layer 10C and form ohmic contact with the second conductivity type semiconductor layer 10C, and distribute the current from the main electrode 18B uniformly to the second conductivity type semiconductor layer 10C. In one embodiment of this application, the extending electrodes 18C extend from all sides of the second conductivity type semiconductor layer 10C, and onto the second conductivity type semiconductor layer 10C to form ohmic contact with it. In another embodiment of this application, the extending electrodes 18C extend from two diagonal corners of the second conductivity type semiconductor layer 10C, and onto the second conductivity type semiconductor layer 10C to form ohmic contact with it. In still another embodiment of this application, the extending electrodes 18C extend from two opposite sides of the second conductivity type semiconductor layer 10C, and onto the second conductivity type semiconductor layer 10C to form ohmic contact with it. In still another embodiment of the application, the extending electrodes 18C extend, with a substantially equal distance between every two extending electrodes 18C, from all sides of the second conductivity type semiconductor layer 10C, and onto the second conductivity type semiconductor layer 10C to form ohmic contact with it. In still another embodiment of this application, the extending electrodes 18C extend substantially toward the center of the second conductivity type semiconductor layer 10C. The width of the extending electrode 18C is less than the width of the main electrode 18B to reduce the area shaded. The width of the extending electrode 18C is, for example, between about 1 μm and 30 μm, and preferably between 1 μm and 10 μm. If the width of the extending electrode. 18C is too broad, the area shaded increases and light extraction efficiency decreases. if the width of the extending electrode. 18C is too narrow, it is not able to conduct and disperse the current effectively.

in other embodiments of this application, the first electrode structure 18 may further comprise auxiliary electrodes 18D which extend from the extending electrodes 18C to an area of the second conductivity type semiconductor layer 10C that is not covered by the extending electrodes 18C. The auxiliary electrodes 18D can further distribute the current more uniformly to the second conductivity type semiconductor layer 10C. The width of the auxiliary electrode 18D is less than the width of the extending electrode 18C in order to reduce the area shaded. The width of the auxiliary electrode 18D is, for example, between about 0.5 μm to 5 μm, and preferably between 0.5 μm and 3 μm. if the width of the auxiliary electrode. l8D is too broad, the area shaded increases and light extraction efficiency decreases. if the width of the auxiliary electrode 18D is too narrow, it is not able to disperse the current effectively. According to the considerations such as the current conduction and the light extraction efficiency, the electrode pad 18A, the main electrode 18B, extending electrodes 18C, and auxiliary electrodes 18D of the first electrode structure 18 may have different thicknesses respectively, or have substantially same thickness formed by a single process. The material of the first electrode structure 18 comprises metal and metal alloy, such as one material selected from a group consisting of gold, silver, copper, aluminum, titanium, chromium, molybdenum rhodium, and platinum, and alloys thereof. Or the material of the first electrode structure 18 comprises a transparent conductive material. in one embodiment of this application, the metal reflective layer 19 is optionally formed between the carrier 12 and the first conductivity type semiconductor layer 10A to increase the light extraction efficiency. As shown in FIG. 1B a second electrode structure 21 is disposed on the other side 12B of the carrier 12. The second electrode structure 21 is coupled to the first conductivity type semiconductor layer 10A with a conductive path through the carrier 12, bonding layer 14, and the reflective layer 19. The light-emitting device 100 as shown in FIG. 1A to 1C is now completely illustrated.

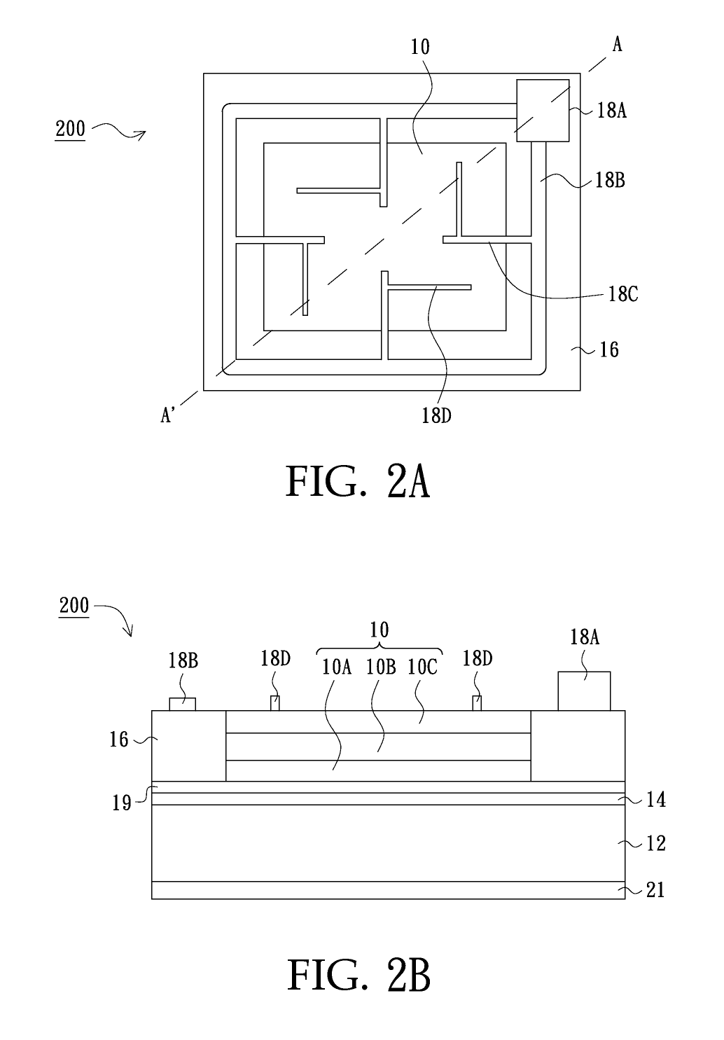

FIG. 2A shows the top view of the light-emitting device 200 in accordance with another embodiment of the present application, and the cross section view along A-A′ direction is shown in FIG. 2B. Some parts of the light-emitting device 200 that are similar to those of the light-emitting device 100 are not described again. The top surface of the insulating structure 16 of the light-emitting device 200 is substantially of the same height as that of the semiconductor light-emitting stack layer 10, and the poor coverage of the extending electrode 18C at the corner caused by the height difference as shown in FIG. 1C can be avoided. The material of the insulating structure 16 comprises one material selected from a group consisting of silicon dioxide, silicon nitride, or aluminum oxide, and SOG (Spin-On-Glass).

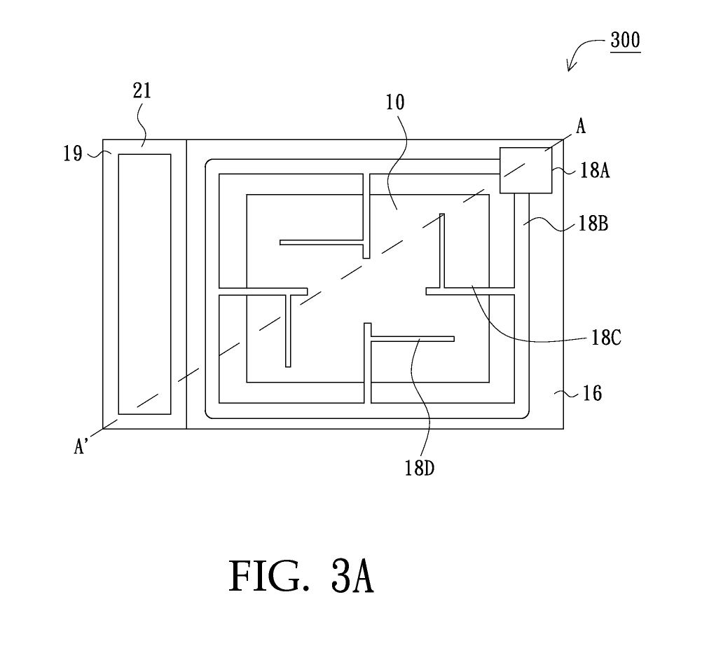

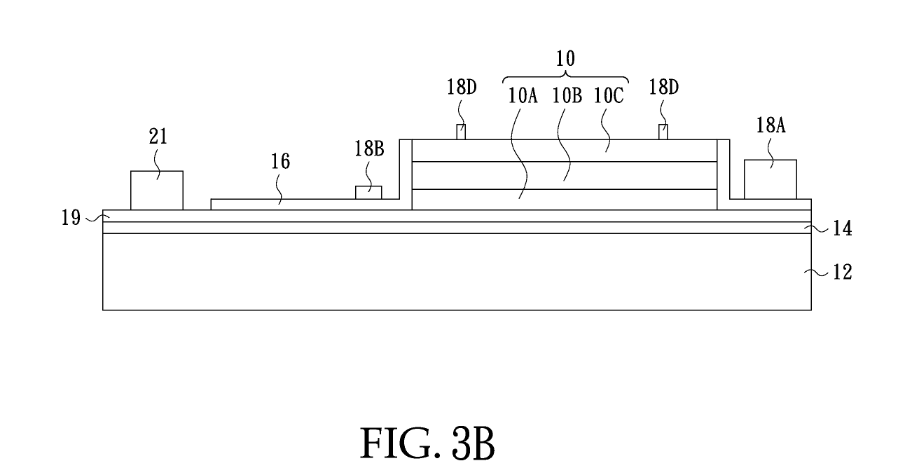

FIG. 3A shows the top view of the light-emitting device 300 in accordance with another embodiment of the present application, and the cross section view along A-A′ direction is shown in FIG. 3B. Unlike the aforementioned light-emitting devices 100 and 200, the light-emitting device 300 is a horizontal type, rather than a vertical one. For the light emitting device 300, some part of the insulating structure 16 is removed to expose part of the conductive metal reflective layer 19, and a second electrode structure 21 is formed on the exposed part of the metal reflective layer 19, so that the second electrode structure 21 forms ohmic contact with the metal reflective layer 19, and is electrically coupled to the first conductivity type semiconductor layer 10A. In another embodiment of the application, the bonding layer 14 in FIG. 3B comprises an insulating material to form electrical isolation with the carrier 12. The material of the bonding layer 14 comprises oxide, nitride, or organic material, wherein the oxide comprises, for example, silicon dioxide, aluminum oxide, or titanium dioxide; the nitride comprises materials such as silicon nitride or silicon oxynitride; the organic material comprises materials such as epoxy, silicone, benzocyclobutene (BCB), or perfluorocyclobutane in another embodiment of the application, the carrier 12 comprises a high thermal conductivity material such as one material selected from a group consisting of aluminum nitride (AlN), zinc oxide (ZnO), silicon carbide, diamond-like carbon (DLC), and CVD diamond. The carrier 12 may also be an electrical insulator, so that the semiconductor light-emitting stack layer 10 may be directly bonded to the carrier 12 with a conductive bonding layer 14, and the metal reflective layer 19 may be disposed between the bonding layer 14 and the first conductivity type semiconductor layer 10A. The material of the bonding layer 14 comprises metal or metal alloy, such as one material selected from a group consisting of gold, silver, aluminum, indium, tin, and lead, and the alloy thereof, or metal oxides such as indium tin oxide and other conductive materials.

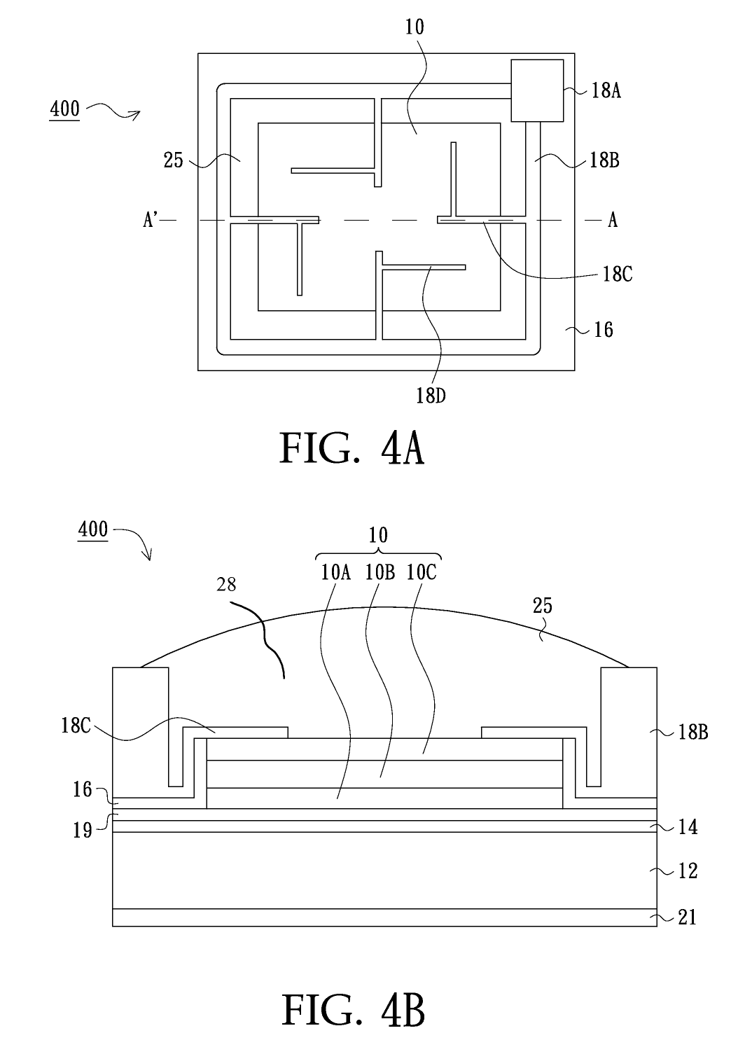

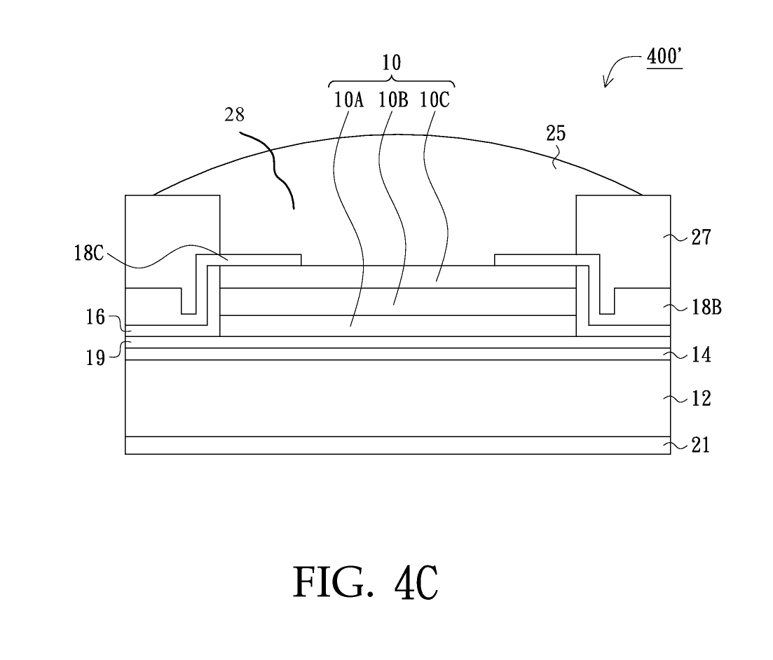

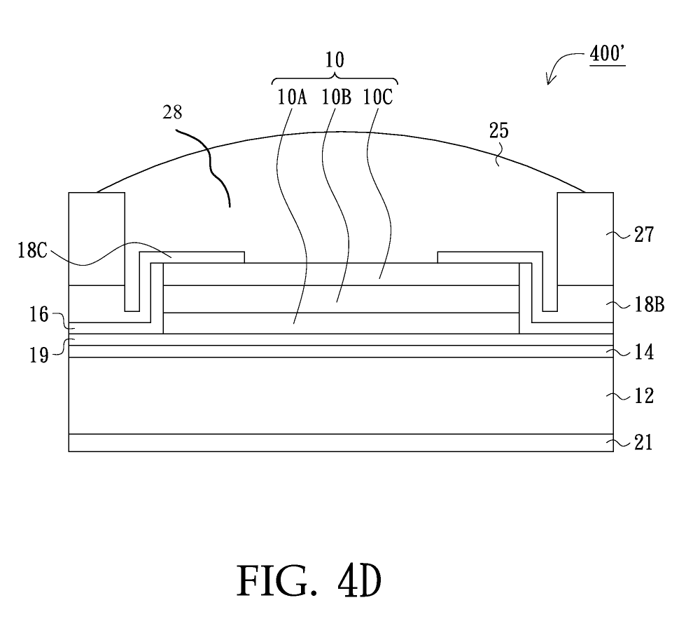

FIG. 4A shows the top view of the light-emitting device 400 in accordance with another embodiment of the present application, and the cross section view along A-A′ direction is shown in FIG. 4B. The parts of light-emitting device 400 that are similar to those of the light-emitting device 100 are not described again. The top surface of the main electrode 18B of the light-emitting device 400 is higher than that of the semiconductor light-emitting stack layer 10, and a recess area 28 is defined. A wavelength conversion structure 25 is filled into the recess area 28. The wavelength conversion structure 25 converts the light emitted by the semiconductor light-emitting stack layer 10 to light with different spectral characteristics. For example, light emitted from the semiconductor light-emitting stack layer 10 with a material of GaN-based series is blue light comprising a peak -wavelength of about from 440 nm to 470 nm. This blue light can excite phosphors to different colors in the wavelength conversion structure 25. in one embodiment of the application, the wavelength conversion structure 25 comprises a red phosphor and green phosphor. Part of the light emitted from the semiconductor light-emitting stack layer 10 can excite both the red phosphor and the green phosphor in the wavelength conversion structure 25 to emit red light comprising a peak wavelength of about from 600 nm to 650 nm and green light comprising a peak wavelength of about from 500 nm to 560 nm. And the blue, red, and green lights are mixed to form white light in another embodiment of the application, the wavelength conversion structure 25 comprises a yellow phosphor, and part of the blue light emitted from the semiconductor light-emitting stack layer 10 can excite the yellow phosphor in the wavelength conversion structure 25 to emit yellow light comprising a peak wavelength of about from 570 nm to 595 nm. And the blue and yellow lights are mixed to form white light with a color temperature of about 5000K˜7000K. in still another embodiment of the application, the wavelength conversion structure 25 comprises a red phosphor and yellow phosphor. Part of the blue light emitted from the semiconductor light-emitting, stack layer 10 can excite both the red phosphor and the yellow phosphor in the -wavelength conversion structure 25 to emit red light comprising a peak wavelength of about from 600 nm to 650 nm, and yellow light comprising a peak wavelength of about from 570 nm to 595 nm. And the blue, red, and yellow lights are mixed to form warm white light with a color temperature of about 2700K˜5000K. in another embodiment, the wavelength conversion structure 25 comprises nano-particles or quantum dots with an energy band gap smaller than that of the active layer 10B. The nano-particles are particles with a size of nanometer scale, for example, particles with a size of about from 10 nm to 1000 nm; the quantum dots are particles with a size of about from 1 nm to 50 nm. The materials for the nano-particles or quantum dots comprise Il-Vi group semiconductors, III-V group semiconductors, organic phosphors materials, and inorganic phosphor materials, with an energy band gap smaller than that of the active layer 10B. The height difference between the main electrode 18B and the semiconductor light-emitting stack layer 10 depends on the amount of phosphors to be spread on the semiconductor light-emitting stack layer 10. In order to control the volume or weight of the spread wavelength conversion structure 25, and thus to control the color temperature of the white or warm white light, the height difference is between about 5 μm and 100 μm. The method to form the wavelength conversion structure 25 may be mixing and dispersing the phosphor powders in a gel, and then disposing the gel containing the phosphor powders in the recess area 28 to form a phosphor layer. Besides, the method to form the wavelength conversion structure 25 may also be forming phosphors powders in the recess area 28 by sedimentation method, and then covering the layer of phosphors powders with a gel to fix the layer of phosphors powders, to form the wavelength conversion structure 25 with a plurality of layers, wherein the phosphor powders do not substantially contain gel, and the gel does not substantially contain phosphors powders. As shown in FIG. 4B, the wavelength conversion structure 25 may be formed only in the recess area 28 defined by the main electrode 18B, or may exceed the main electrode 18B by a height difference to form a convex outer surface. The main electrode 18B does not cover the semiconductor light-emitting stack layer 10, and is separated from the semiconductor light-emitting stack layer 10 with a gap, so that the wavelength conversion structure 25 can cover sidewalls of the semiconductor light-emitting stack layer 10. In addition to a structure formed by the material of GaN-based series, the semiconductor light-emitting stack layer 10 may also be a structure formed by the material of AlGaInP-based series or other suitable structure. In addition to the blue light, by using different materials for the active layer, the semiconductor light-emitting stack layer 10 may emit visible lights with other colors, infrared, near-ultraviolet, or UV.

FIG. 4C shows the cross section view of the light-emitting device 400′ in accordance with another embodiment of the present application. The parts of the light-emitting, device 400′ that are similar to those of the light-emitting device 100 are not described again. The light-emitting device 400′ further comprises a protective structure 27 formed on the main electrode 18B and around the semiconductor light-emitting stack layer 10. The top surface of the protective structure 27 is higher than that of the semiconductor light-emitting stack layer 10, and a recess area 28 is defined. The protective structure 27 protects the light-emitting device from deterioration caused by environmental factors such as humidity or ultraviolet light. The materials for the protection structure 27 comprises one material selected from a group consisting of silicon dioxide, silicon nitride, aluminum oxide, gallium phosphide, calcium fluoride, magnesium fluoride, and barium fluoride. The height difference between the protection structure 27 and the semiconductor light-emitting stack layer 10 depends on the amount of phosphors to be spread on the semiconductor light-emitting stack layer 10. In order to control the volume or weight of the spread wavelength conversion structure 25, and thus to control the color temperature of the white or warm white light, the height difference is between about 5 μm and 100 μm. The wavelength conversion structure 25 is filled into the recess area 28 to convert the light emitted by the semiconductor light-emitting stack layer 10 to light with different spectral characteristics. The composition and the principle for the wavelength conversion structure 25, which have been previously described in the relevant paragraphs in FIG. 4B, are not described again. In another embodiment of this application, as shown in FIG. 4D, the protective structure 7 may not cover the semiconductor light-emitting stack layer 10, and is separated from the semiconductor light-emitting stack layer 10 with a gap, so that the wavelength conversion structure 25 can cover side walls of the semiconductor light-emitting stack layer 10.

it is noted that, the recess area 28 and the wavelength conversion structure 25 as shown in FIGS. 4B to 4D can be further applied to other structures in the present application. For example, the insulating structure 16 with a same height as that of the semiconductor light-emitting stack layer 10 shown in FIG. 2B can be combined with the main electrode 18B in FIG. 4B or the protection structure 27 in FIG. 4C to define the recess area 28 for the wavelength conversion structure 25. On the other hand, the recess area 28 and the wavelength conversion structure 25 are not limited to applications for the vertical type light-emitting devices shown in FIGS. 4A-4D, and they can also be applied to the horizontal type light-emitting devices in FIGS. 3A-3B.

The foregoing description has been directed to the specific embodiments of this application. It will be apparent; however, that other alternatives and modifications may be made to the embodiments without escaping the spirit and scope of the application.

What is claimed is:

1. A light-emitting device comprising:
a carrier comprising a first side and a second side;
a semiconductor light-emitting stack layer on the first side of the carrier, the semiconductor light-emitting stack layer comprising a first conductivity type semiconductor layer, an active layer, and a second conductivity type semiconductor layer; and
a first electrode structure electrically coupled to the second conductivity type semiconductor layer, the first electrode structure comprising:
a main electrode surrounding the semiconductor light-emitting stack layer;
an extending electrode extending from the main electrode onto the second conductivity type semiconductor layer; and
an electrode pad coupling to the main electrode,
wherein the main electrode is formed on an area of the carrier not covered by the semiconductor light-emitting stack layer.

2. The light-emitting device as claimed in claim 1, further comprising an insulating structure on the sidewalls of the semiconductor light-emitting stack layer and having a top surface.

3. The light-emitting device as claimed in claim 1, further comprising a reflective layer between the semiconductor light-emitting stack layer and the carrier.

4. The light-emitting device as claimed in claim 1, further comprising a bonding layer to bond the semiconductor light-emitting stack layer to the first side of the carrier.

5. The light-emitting device as claimed in claim 2, wherein the top surface of the insulating structure is substantially of the same height as that of the semiconductor light-emitting stack layer.

6. The light-emitting device as claimed in claim 1, further comprising a second electrode structure electrically coupled to the first conductivity type semiconductor layer.

7. The light-emitting device as claimed in claim 6, wherein the second electrode structure is on the first side or the second side of the carrier, and is electrically coupled to the carrier.

8. The light-emitting device as claimed in claim 1, further comprising a protective structure around the semiconductor light-emitting stack layer to define a recess area; and
a wavelength conversion structure filled into the recess area.

9. The light-emitting device as claimed in claim 8, wherein the wavelength conversion structure covers sidewalls of the semiconductor light-emitting stack layer.

10. The light-emitting device as claimed in claim 1, wherein the top surface of the main electrode is higher than that of the semiconductor light-emitting stack layer to define a recess area, and a wavelength conversion structure is filled into the recess area.

11. The light-emitting device as claimed in claim 10, wherein the wavelength conversion structure covers sidewalls of the semiconductor light-emitting stack layer.

12. The light-emitting device as claimed in claim 1, wherein the width of the main electrode is larger than or equal to the width of the extending electrode.

13. The light-emitting device as claimed in claim 1, wherein the area of the semiconductor light-emitting stack layer is between 0.25 mm² and 25 mm².

14. The light-emitting device as claimed in claim 1, wherein the main electrode is separated from the semiconductor light-emitting stack layer with a gap.

15. The light-emitting device as claimed in claim 1, wherein the electrode pad is formed on an area of the carrier not covered by the semiconductor light-emitting stack layer.

16. The light-emitting device as claimed in claim 4, wherein the semiconductor light-emitting stack layer does not comprise a growth substrate.
